(19) United States
(12) Patent Application Publication
(10) Pub. No.: US 2026/0190625 A1
(43) Pub. Date: Jul. 2, 2026

(54) DISPLAY DEVICE, METHOD OF MANUFACTURING DISPLAY DEVICE, AND ELECTRONIC DEVICE INCLUDING THE SAME

(71) Applicant: Samsung Display Co., Ltd., Yongin-si (KR)

(72) Inventors: SUNG-WOOK WOO, Yongin-si (KR); KYOUNG SEOK SON, Yongin-si (KR); HOYOUNG SIM, Yongin-si (KR); SEUNGHUN LEE, Yongin-si (KR); JAEHAN LEE, Yongin-si (KR)

(21) Appl. No.: 19/393,884

(22) Filed: Nov. 19, 2025

(30) Foreign Application Priority Data
Dec. 30, 2024 (KR) 10-2024-0201183

(51) Int. Cl. H10K 59/121; H10D 30/01; H10D 30/67; H10K 59/12; H10K 102/00

(52) U.S. Cl. CPC H10K 59/1213; H10D 30/0312; H10D 30/6731; H10D 30/6755; H10K 59/1201; H10K 2102/351

(57) ABSTRACT

A display device includes: a transistor on a substrate; and a light-emitting device electrically connected to the transistor, wherein the transistor includes: a first electrode on the substrate; a second electrode spaced apart from the first electrode with a first insulating layer therebetween; a semiconductor layer contacting the first electrode and the second electrode; and a gate electrode overlapping the semiconductor layer with a second insulating layer therebetween, with a recess penetrating the second electrode, the first insulating layer, and the first electrode from an upper surface of the second electrode, a portion of the semiconductor layer and a portion of the gate electrode are within the recess, and within the recess, the semiconductor layer contacts a side surface of the first electrode and a side surface of the second electrode, and a lower surface of the gate electrode is lower than an upper surface of the first electrode.

### CROSS-REFERENCE TO RELATED APPLICATION

The present application claims priority to and the benefit of Korean Patent Application No. 10-2024-0201183, filed on Dec. 30, 2024, in the Korean Intellectual Property Office, the disclosure of which is incorporated by reference herein in its entirety.

### BACKGROUND

### 1. Field

Aspects of some embodiments of the present disclosure relate to a display device, a method of manufacturing the display device, and an electronic device including the same.

### 2. Description of the Related Art

Recently, various types of lightweight and compact flat panel display devices have been developed. Flat panel display devices include liquid crystal displays (LCDs), field emission displays (FEDs), plasma display panels (PDPs), and organic light emitting displays.

Among flat panel displays, organic light emitting displays display images using organic light emitting diodes (OLEDs), which emit light through the recombination of electrons and holes. These organic light emitting diode displays have come to prominence as next-generation displays because they have fast response speeds and operate with low power consumption.

### SUMMARY

Aspects of some embodiments of the present disclosure include a display device with relatively improved electrical characteristics, a method of manufacturing the display device, and an electronic device including the same.

However, the characteristics of embodiments according to the present disclosure are not limited to the characteristics described above, and other characteristics not mentioned may be more clearly understood by those skilled in the art from the description of the disclosure described below.

According to some embodiments of the present disclosure, a display device includes a substrate, a transistor on the substrate, and a light-emitting device electrically connected to the transistor, wherein the transistor includes a first electrode positioned on the substrate, a second electrode spaced apart from the first electrode in a vertical direction with a first insulating layer therebetween, a semiconductor layer in contact with the first electrode and the second electrode, and a gate electrode overlapping the semiconductor layer with a second insulating layer therebetween, a recess penetrating the second electrode, the first insulating layer, and the first electrode from an upper surface of the second electrode is defined, at least a portion of the semiconductor layer and at least a portion of the gate electrode are located within the recess, and within the recess, the semiconductor layer is in contact with a side surface of the first electrode and a side surface of the second electrode, and a lower surface of the gate electrode is positioned at a lower height than an upper surface of the first electrode.

According to some embodiments, a shape of the gate electrode may correspond to a shape of the semiconductor layer.

According to some embodiments, the semiconductor layer may extend outwardly of the recess on the upper surface of the second electrode.

According to some embodiments, the first insulating layer may have a multilayer structure including a silicon nitride layer and a silicon oxide layer.

According to some embodiments, the silicon nitride layer may be spaced apart from the semiconductor layer.

According to some embodiments, the first insulating layer may include a first silicon oxide layer, a silicon nitride layer, and a second silicon oxide layer sequentially stacked on the substrate.

According to some embodiments, the substrate may have a first thickness overlapping the recess and a second thickness outside the recess, the first thickness being less than a second thickness, and at a position overlapping the recess, a lower surface of the semiconductor layer may be positioned at a lower height than an upper surface of the substrate outside the recess.

According to some embodiments, a thickness of the first electrode may be less than a sum of a thickness of the semiconductor layer and a thickness of the second insulating layer.

According to some embodiments, the semiconductor layer may include an oxide semiconductor.

According to some embodiments, the transistor may include a switching transistor.

According to some embodiments of the present disclosure, in a method of manufacturing a display device, the method includes sequentially forming a first electrode, a first insulating layer, and a second electrode on a substrate, patterning the first electrode, the first insulating layer and the second electrode to form a recess penetrating the second electrode, the first insulating layer and the first electrode from an upper surface of the second electrode, forming a semiconductor layer and a second insulating layer within at least the recess, and forming a gate electrode on the second insulating layer, wherein a lower surface of the gate electrode is positioned at a lower height than an upper surface of the first electrode.

According to some embodiments, the method may further include etching a portion of the substrate, after the forming of the recess.

According to some embodiments, the substrate may have a first thickness overlapping the recess and a second thickness outside the recess, the first thickness being less than a second thickness, and at a position overlapping the recess, a lower surface of the semiconductor layer may be positioned at a lower height than an upper surface of the substrate outside the recess.

According to some embodiments, the semiconductor layer may include an oxide semiconductor.

According to some embodiments, the forming of the semiconductor layer and the second insulating layer may include adjusting a concentration of oxygen vacancies in the semiconductor layer by adjusting a concentration of oxygen when forming the semiconductor layer or performing a heat treatment when the semiconductor layer is formed.

According to some embodiments, a shape of the gate electrode may correspond to a shape of the semiconductor layer.

According to some embodiments, within the recess, the semiconductor layer may be in contact with a side surface of the first electrode and a side surface of the second electrode.

According to some embodiments, the first insulating layer may have a multilayer structure including a silicon nitride layer and a silicon oxide layer.

According to some embodiments, the silicon nitride layer may be spaced apart from the semiconductor layer.

According to some embodiments, the method may further include forming a light-emitting device electrically connected to the transistor.

According to some embodiments of the present disclosure, an electronic device includes a memory storing at least one program, a processor configured to operate by executing the at least one of the program, a display device configured to receive data from the processor and provide visual information, and a power module supplying power to the display device, wherein the display device includes a substrate, a transistor on the substrate, and a light-emitting device electrically connected to the transistor, wherein the transistor includes a first electrode positioned on the substrate, a second electrode spaced apart from the first electrode with a first insulating layer therebetween, a semiconductor layer in contact with the first electrode and the second electrode, and a gate electrode overlapping the semiconductor layer with a second insulating layer therebetween, a recess penetrating the second electrode, the first insulating layer, and the first electrode from an upper surface of the second electrode is defined, at least a portion of the semiconductor layer and at least a portion of the gate electrode are located within the recess, and within the recess, the semiconductor layer is in contact with a side surface of the first electrode, a side surface of the second electrode, and a bottom surface of the recess, and a lower surface of the gate electrode is positioned at a lower height than an upper surface of the first electrode.

According to some embodiments, the substrate may have a first thickness overlapping the recess and a second thickness outside the recess, the first thickness being less than a second thickness, and at a position overlapping the recess, a lower surface of the semiconductor layer may be positioned at a lower height than the upper surface of the substrate outside the recess.

According to some embodiments, a thickness of the first electrode may be less than a sum of a thickness of the semiconductor layer and a thickness of the second insulating layer.

According to some embodiments, a resolution of the display device may include 1500 ppi (pixels per inch) to 7000 ppi.

### BRIEF DESCRIPTION OF THE DRAWINGS

The following drawings attached to this specification illustrate embodiments of the present disclosure and, together with the detailed description of the disclosure described below, serve to further understand the technical idea of the present disclosure; therefore, the present disclosure should not be interpreted as being limited to matters described in such drawings.

FIG. 1 is a plan view schematically illustrating an example of a display device according to some embodiments of the present disclosure.

FIG. 2 is a block diagram schematically illustrating a structure of the display device of FIG. 1.

FIG. 3 is a circuit diagram illustrating an example of an equivalent circuit of a sub-pixel of the display device of FIG. 1.

FIG. 4 is a cross-sectional view schematically illustrating aspects of a transistor located in a sub-pixel included in the display device of FIG. 1.

FIGS. 5 to 8 are cross-sectional views schematically illustrating aspects of a method of manufacturing the transistor of FIG. 4.

FIG. 9 is a cross-sectional view schematically illustrating aspects of a transistor located in a sub-pixel included in the display device of FIG. 1.

FIG. 10 is a cross-sectional diagram schematically illustrating aspects of a transistor located in a sub-pixel included in the display device of FIG. 1.

FIG. 11 is a cross-sectional diagram schematically illustrating aspects of a transistor located in a sub-pixel included in the display device of FIG. 1.

FIG. 12 is a block diagram of an electronic device according to some embodiments.

FIG. 13 is a schematic diagram of electronic devices according to some embodiments.

### DETAILED DESCRIPTION

The present disclosure may apply various transformations and have various embodiments, specific embodiments are illustrated in the drawings and described in detail in the detailed description. Effects and features of the present disclosure, and methods for achieving them will become clear with reference to the embodiments described below in detail together with the drawings. However, the present disclosure is not limited to the embodiments disclosed below and may be implemented in various forms.

In the following embodiments, the terms first, second, and the like do not have limited meaning but are used for the purpose of distinguishing one component from another component.

In the following embodiments, the expressions used in the singular such as “a,” “an,” and “the” are intended to include the plural forms as well, unless the context clearly indicates otherwise.

In the following embodiments, it will be understood that the terms such as “including,” “comprising,” and “having” specify the presence of stated features or components, but do not preclude the presence or addition of one or more other features or components.

In the following examples, when a part, such as a film, region, component, etc. is mentioned to be on or above another part, it includes not only a case in which the part is directly on top of the other part, but also a case in which another film, region, component, etc. is interposed in between.

In the drawings, components may be exaggerated or reduced in size for convenience of description. For example, the sizes and thicknesses of the respective components shown in the drawings are arbitrarily shown for convenience of description, and thus one or more embodiments are not necessarily limited thereto.

Hereinafter, aspects of some embodiments of the present disclosure will be described in more detail with reference to the accompanying drawings, and when described with reference to the drawings, the same or corresponding components are given the same reference numerals.

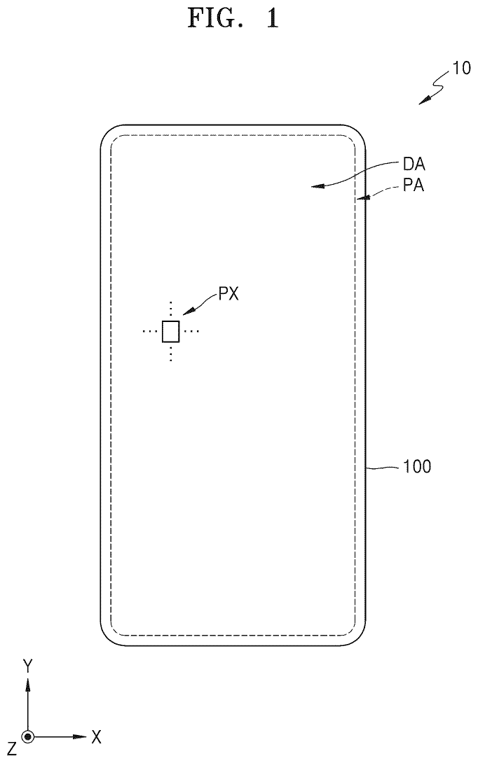

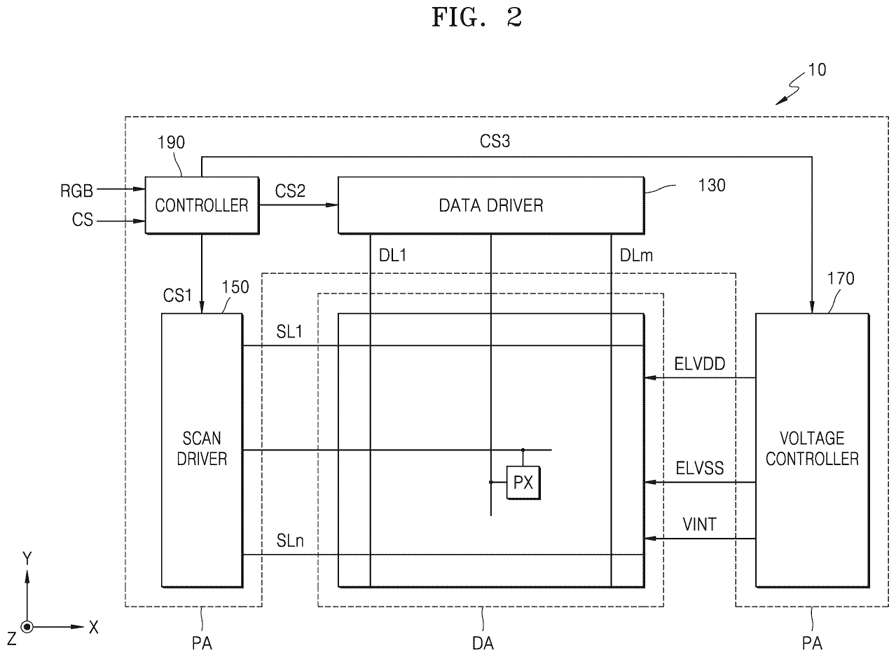

FIG. 1 is a plan view schematically illustrating an example of a display device 10 according to some embodiments of the present disclosure, and FIG. 2 is a block diagram schematically illustrating a structure of the display device 10 of FIG. 1.

Referring to FIGS. 1 and 2, the display device 10 according to some embodiments of the present disclosure may include the substrate 100 including a display region DA displaying images and a peripheral region PA located outside (e.g., in a periphery or outside a footprint of) the display region DA.

The display region DA may include a plurality of scan lines SL1, . . . , SLn extending in a first direction X, a plurality of data lines DL1, . . . , DLm extending in a second direction Y perpendicular to the first direction X, and a plurality of sub-pixels PX. Here, m and n are each natural numbers.

Lines capable of applying electrical signals to a plurality of sub-pixels PX may include the plurality of scan lines SL1, . . . , SLn, the plurality of data lines DL1, . . . , DLm, etc. The plurality of scan lines SL1, . . . , SLn may be arranged in a plurality of rows extending in the first direction X, for example, to transmit scan signals to the sub-pixels PX, the plurality of data lines DL1, . . . , DLm may be arranged in a plurality of columns extending in the second direction Y, for example, to transmit data signals to the sub-pixels PX, and the plurality of sub-pixels PX may be positioned at intersections of the plurality of scan lines SL1, . . . , SLn and the plurality of data lines DL1, . . . , DLm.

Each sub-pixel PX may include a light-emitting device to emit red, green, blue, or white light. For example, each sub-pixel PX may include, but is not limited to, an organic light emitting diode OLED as a light-emitting device.

In the peripheral region PA, a data driver 130 that provides data signals to the display region DA, a scan driver 150 that provides scan signals to the display region DA, a voltage controller 170 that controls voltages supplied to the display region DA, and a controller 190 that may control the data driver 130, scan driver 150, and voltage controller 170 may be arranged.

The voltage controller 170 may generate and control a first voltage ELVDD, a second voltage ELVSS, and an initialization voltage VINT provided to the display region DA.

The first voltage ELVDD, the second voltage ELVSS, and the initialization voltage VINT may be applied to the plurality of sub-pixels PX. For example, the first voltage ELVDD may be a positive voltage, and the second voltage ELVSS may be a negative voltage or ground voltage. That is, the second voltage ELVSS may have a lower level than that of the first voltage ELVDD.

The controller 190 may receive image signals RGB and a control signal CS from the outside (e.g., a system board). The controller 190 may convert a data format of the image signals RGB to match interface specifications of the data driver 130 and generate image data DATA. The controller 190 may provide the image data DATA, which has been generated by converting the data format of the image signals RGB, to the data driver 130.

The controller 190 may generate and output a first control signal CS1 and a second control signal CS2 in response to the control signal CS provided from the outside. The first control signal CS1 may be defined as a scan control signal, and the second control signal CS2 may be defined as a data control signal. The first control signal CS1 may be provided to the scan driver 150. The second control signal CS2 may be provided to the data driver 130.

The scan driver 150 may generate a plurality of scan signals in response to the first control signal CS1. The plurality of scan signals may be applied to the plurality of sub-pixels PX via the plurality of scan lines SL1, . . . , SLn.

The data driver 130 may generate a plurality of data voltages corresponding to the image data DATA in response to the second control signal CS2. The plurality of data voltages may be applied to the plurality of sub-pixels PX via the data lines DL1, . . . , DLm. The data driver 130 may simultaneously (or concurrently) provide the data voltages generated in units of sub-pixel rows to the plurality of sub-pixels PX via the data lines DL1, . . . , DLm.

The plurality of sub-pixels PX may receive the plurality of data voltages in response to the plurality of scan signals. The plurality of sub-pixels PX may display images by emitting light with a brightness corresponding to the plurality of data voltages. The plurality of sub-pixels PX may display the images by emitting light sequentially or simultaneously (or concurrently).

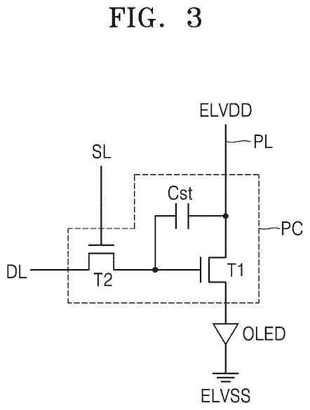

FIG. 3 is a circuit diagram illustrating an example of an equivalent circuit of a sub-pixel of the display device of FIG. 1. Although FIG. 3 illustrates various components in a sub-pixel according to some embodiments, embodiments according to the present disclosure are not limited thereto, and according to some embodiments, the sub-pixel may include additional components without departing from the spirit and scope of embodiments according to the present disclosure.

Referring to FIG. 3, a pixel circuit PC may be connected to a display element, for example, an organic light emitting diode OLED. The pixel circuit PC may be placed in the display region DA. The pixel circuit PC may include a driving thin film transistor T1, a switching thin film transistor T2, and a storage capacitor Cst. The organic light emitting diode OLED may emit red, green, or blue light, or may emit red, green, blue, or white light.

The switching thin film transistor T2 may be connected to the scan line SL and the data line DL and may transmit the data signal or data voltage input from the data line DL to the driving thin film transistor T1 based on the scan signal or switching voltage input from the scan line SL. The storage capacitor Cst may be connected to the switching thin film transistor T2 and a driving voltage line PL and may store a voltage corresponding to a difference between a voltage received from the switching thin film transistor T2 and the first voltage ELVDD supplied to the driving voltage line PL.

The driving thin film transistor T1 may be connected to the driving voltage line PL and the storage capacitor Cst and may control driving current flowing through the organic light emitting diode OLED from the driving voltage line PL in response to the voltage value stored in the storage capacitor Cst. The organic light emitting diode OLED may emit light with a certain brightness depending on the driving current. A counter electrode of the organic light emitting diode OLED may be supplied with the second voltage ELVSS.

Although FIG. 3 illustrates that the pixel circuit PC includes two thin film transistors and one storage capacitor, the pixel circuit PC may include three, four, five or more thin film transistors, and the pixel circuit PC may include two, three or more capacitors.

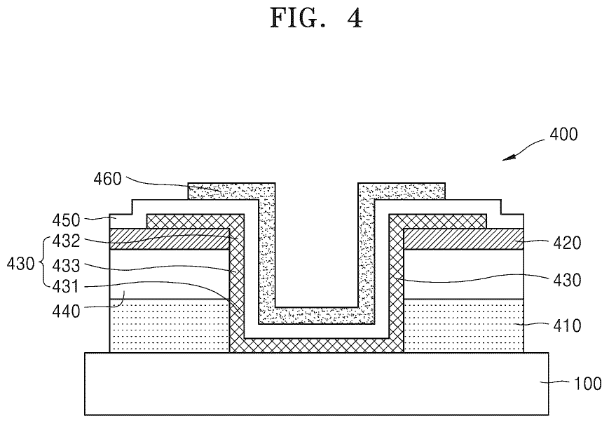

FIG. 4 is a cross-sectional view schematically illustrating aspects of a transistor 400 located in a sub-pixel included in the display device 10 of FIG. 1.

Referring to FIG. 4, the display device 10 according to some embodiments of the present disclosure may include a substrate 100, the transistor 400 on the substrate 100, and a light-emitting device electrically connected to the transistor 400. The transistor 400 may be a vertical thin-film transistor in which a channel is formed in a direction perpendicular to the substrate 100. In addition, the transistor 400 may be a driving transistor that controls current flowing through the light-emitting device or a switching transistor that controls ON/OFF of current.

The transistor 400 may include a first electrode 410 positioned on the substrate 100, a second electrode 420 spaced apart from the first electrode 410 in a vertical direction with a first insulating layer 440 therebetween, and a semiconductor layer 430 in contact with the first electrode 410 and the second electrode 420.

A recess penetrating the second electrode 420, the first insulating layer 440, and the first electrode 410 from an upper surface of the second electrode 420 may be defined, at least a portion of the semiconductor layer 430 may be positioned within the recess, and within the recess, the semiconductor layer 430 may be in contact with a side surface of the first electrode 410, a side surface of the second electrode 420, and a bottom surface of the recess. In addition, the semiconductor layer 430 may extend outwardly from the recess on the upper surface of the second electrode 420 and may contact the upper surface of the second electrode 420. That is, as illustrated in FIG. 4, the semiconductor layer 430 may include a first portion of the semiconductor layer 430 positioned within the recess and a second portion of the semiconductor layer 430 positioned outside the recess.

According to some embodiments, herein, a ‘recess’ may be formed by penetrating the second electrode 420, the first insulating layer 440, and the first electrode 410 in a stacking direction of the second electrode 420, the first insulating layer 440, and the first electrode 410. Also, referring to FIG. 4, although the recess is illustrated as having an angular shape, embodiments according to the present disclosure are not limited thereto, and the recess may also have a concave shape of a curved shape or an inclined shape.

According to some embodiments, the substrate 100 may include a transparent glass material or silicon (Si) with SiO₂ as a main component. However, without being limited thereto, the substrate 100 may also be formed of a transparent plastic material. Plastic materials may include polyethersulfone (PES), polyacrylate (PAR), polyetherimide (PEI), polyethylene naphthenate (PEN), polyethylene terephthalate (PET), polyphenylene sulfide (PPS), polyallylate, polyimide, polycarbonate (PC), cellulose triacetate (TAC), cellulose acetate propionate (CAP), etc.

For example, if the substrate 100 is silicon, the display device 10 may be, but is not limited to, OLED on silicon (OLEDos) or LED on silicon (LEDoS).

According to some embodiments, the substrate 100 may have a multilayer structure including a base layer including the aforementioned polymer resin and a barrier layer. The substrate 100 including a polymer resin may have flexible, rollable, and bendable properties.

According to some embodiments, a buffer layer may be formed on the substrate 100. The buffer layer may block impurities during a crystallization process to form polycrystalline silicon, thereby relatively improving the characteristics of the polycrystalline silicon and provide a flat or planar surface on the buffer layer.

On the substrate 100, the first electrode 410, the second electrode 420 spaced apart in the vertical direction from the first electrode 410 with the first insulating layer 440 therebetween, and the semiconductor layer 430 in contact with the first electrode 410 and the second electrode 420 may be formed. For example, the semiconductor layer 430 may be in contact with at least a portion of one surface of the first electrode 410, the first insulating layer 440, and the second electrode 420. That is, the semiconductor layer 430 may contact the side surface of the first electrode 410. The side surface may refer to an inner surface of the aforementioned recess.

The first electrode 410 may be a source electrode, and the second electrode 420 may be a drain electrode. Accordingly, the semiconductor layer 430 in contact with the first electrode 410 may be a source region 431, and the semiconductor layer 430 in contact with the second electrode 420 may be a drain region 432. However, without being limited thereto, and the first electrode 410 may be a drain electrode and the second electrode 420 may be a source electrode.

For example, the semiconductor layer 430 may include the source region 431 and the drain region 432 doped with impurities and a channel region 433 located between the source region 431 and the drain region 432. Here, the impurities may vary depending on the type of transistor 400 and may include an N-type impurity or a P-type impurity. That is, the channel region 433, the source region 431 located on one side of the channel region 433, and the drain region 432 located on the other side of the channel region 433 may be referred to as the semiconductor layer 430.

Here, the semiconductor layer 430 may be a layer including an oxide semiconductor. For example, the semiconductor layer 430 may include indium gallium zinc oxide (IGZO). However, without being limited thereto, the semiconductor layer 430 may include polycrystalline silicon.

According to some embodiments, the transistor 400 may further include a gate electrode 460 overlapping the semiconductor layer 430 with the second insulating layer 450 therebetween. Here, the shape of the gate electrode 460 may correspond to the shape of the semiconductor layer 430. At least a portion of the gate electrode 460 may be positioned within the recess. That is, as illustrated in FIG. 4, the gate electrode 460 may include a first portion of the gate electrode 460 positioned within the recess and a second portion of the gate electrode 460 positioned outside the recess.

According to some embodiments, when voltage is applied to the gate electrode 460, the channel region 433 overlapping the gate electrode 460 may be opened upon receiving an electric field. Accordingly, current may flow from the first electrode 410 to the second electrode 420 through the opened channel region 433. However, without being limited thereto, the current may flow from the second electrode 420 to the first electrode 410 through the opened channel region 433.

When the thickness of the first electrode 410 is greater than the sum of the thickness of the semiconductor layer 430 and the thickness of the second insulating layer 450, a lower surface of the gate electrode 460 may be located below an upper surface of the first electrode 410. Alternatively, the lower surface of the gate electrode 460 may be positioned at a lower height than that of the upper surface of the first electrode 410. In this case, the entire region of the channel region 433 may overlap the gate electrode 460, and thus, the entire region of the channel region 433 may receive the electric field of the gate electrode 460.

In this specification, the “lower surface of the gate electrode 460” may be interpreted as the lowermost surface of the gate electrode 460, and the “upper surface of the first electrode 410” may be interpreted as the uppermost surface of the first electrode 410. In addition, in that the “lower surface of the gate electrode 460 may be positioned at a lower height than that of the upper surface of the first electrode 410,” “height” may be interpreted as the length measured from the lowermost surface or bottom surface of the substrate 100 in a thickness direction of the substrate 100.

If the lower surface of the gate electrode 460 is positioned above the upper surface of the first electrode 410, a region in which the semiconductor layer 430 and the gate electrode 460 do not overlap in a direction parallel to the upper surface of the substrate 100 may be created. As a result, the region in which the semiconductor layer 430 and the gate electrode 460 do not overlap in a direction parallel to the upper surface of the substrate 100 may act as resistance to deteriorate the electrical performance of the transistor 400.

In addition, if, when forming the transistor 400, a partial region of the first electrode 410 is not etched entirely in the region in which the recess is formed and only an upper portion of the partial region of the first electrode 410 is etched so that the semiconductor layer 430 does not contact only the side surface of the first electrode 410 but contact the upper surface and side surface of the first electrode 410, a region in which the first electrode 410 and the gate electrode 460 overlap in a direction perpendicular to the substrate 100 occurs and parasitic capacitance may occur between the first electrode 410 and the gate electrode 460. As a result, power consumption of the transistor 400 may increase, thereby reducing the energy efficiency of the display device.

However, according to some embodiments of the present disclosure, when the lower surface of the gate electrode 460 is located below the upper surface of the first electrode 410 and the semiconductor layer 430 contacts the side surface (which may have the same meaning as the inner surface of the recess) of the first electrode 410, the entire region of the channel region 433 may receive the electric field of the gate electrode 460 and parasitic capacitance between the first electrode 410 and the gate electrode 460 may be prevented or reduced, so that the electrical characteristics and power efficiency of the display device and the electronic device including the same may be relatively improved.

In addition, according to some embodiments of the present disclosure, when the transistor 400 is a vertical thin film transistor in which a channel is formed in a direction perpendicular to the substrate 100 and the lower surface of the gate electrode 460 is positioned below the upper surface of the first electrode 410, the integration density of the display device 10 may be relatively improved. According to some embodiments, the resolution of the display device 10 may be 1500 ppi (pixels per inch) to 7000 ppi.

According to some embodiments, the gate electrode 460, the first electrode 410, and the second electrode 420 may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu).

In addition, the first insulating layer 440 and the second insulating layer 450 may include silicon nitride and/or silicon oxide.

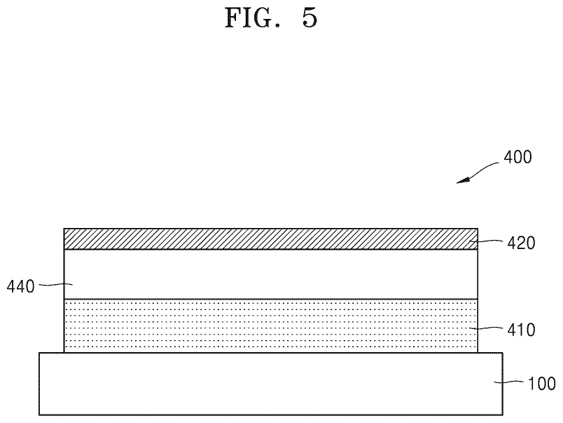

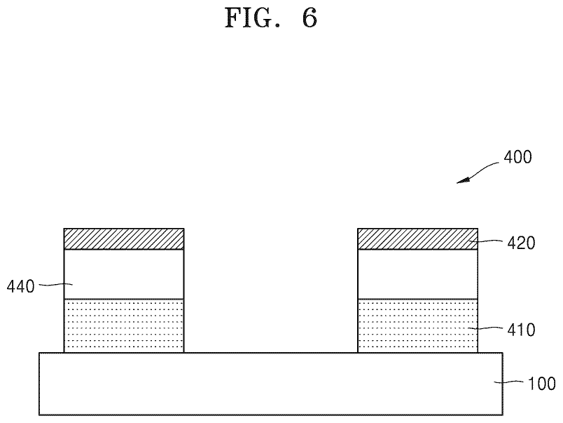

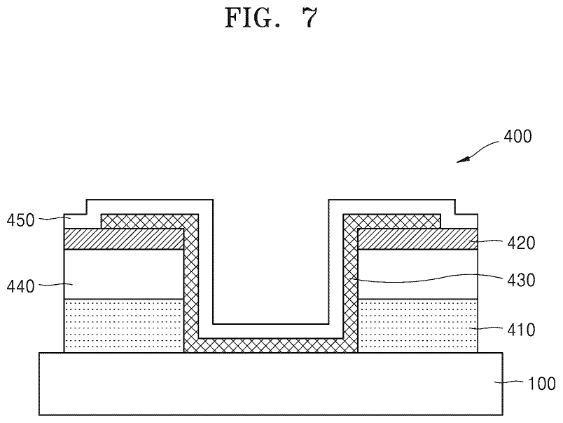

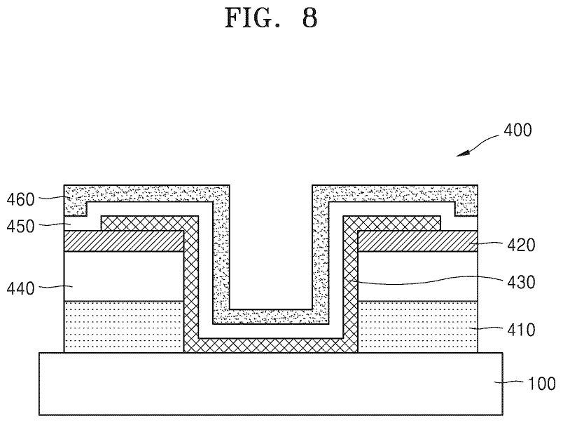

FIGS. 5 to 8 are cross-sectional views schematically illustrating an example of a method of manufacturing the transistor 400 of FIG. 4.

Referring to FIGS. 4 to 8, the method of manufacturing a display device according to some embodiments of the present disclosure may include sequentially forming the first electrode 410, the first insulating layer 440, and the second electrode 420 on the substrate 100, patterning the first electrode 410, the first insulating layer 440, and the second electrode 420 to form a recess penetrating the second electrode 420, the first insulating layer 440, and the first electrode 410 from an upper surface of the second electrode 420, forming the semiconductor layer 430 and the second insulating layer 450 at least within the recess, and forming the gate electrode 460 on the second insulating layer 450.

According to some embodiments, after sequentially forming the first electrode 410, the first insulating layer 440, and the second electrode 420 on the substrate 100, the second electrode 420 to be etched may be exposed through a photolithography process. Thereafter, a dry etch and/or wet etch process may be performed on the second electrode 420 to expose the first insulating layer 440. The etch process herein may include a dry etch process and/or a wet etch process.

An etching process may be performed on the exposed first insulating layer 440 to expose the first electrode 410, and then an etching process may be performed on the exposed first electrode to form a recess penetrating the second electrode 420, the first insulating layer 440, and the first electrode 410. For example, the recess may expose the substrate 100 or a buffer layer on the substrate 100.

Here, it may be desirable to sufficiently etch the first electrode 410 to completely expose the substrate 100 or the buffer layer on the substrate 100. If a subsequent process is performed while the substrate 100 or the buffer layer on the substrate 100 is not fully exposed and the first electrode 410 remains on the substrate 100 or the buffer layer on the substrate 100, as described above, parasitic capacitance may occur between the first electrode 410 and the gate electrode 460, which may increase the power consumption of the display device.

Thereafter, the semiconductor layer 430 is formed to contact the side surface of the first electrode 410, the side surface of the second electrode 420, and the bottom surface of the recess within the recess, extends outwardly of the recess from the upper surface of the second electrode 420, and contacts the second electrode 420, the semiconductor layer 430 is patterned through a photolithography process, and the second insulating layer 450 may then be formed on the semiconductor layer 430.

According to some embodiments, when the semiconductor layer 430 includes an oxide semiconductor, oxygen vacancies may serve as a source of electrons for the semiconductor layer 430, thereby increasing the conductivity of the semiconductor layer 430. Therefore, when forming the semiconductor layer 430 on the second electrode 420 to relatively improve the electrical characteristics of the display device and the electronic device including the same, a process of controlling the concentration of oxygen vacancies in the semiconductor layer 430 may be added.

When forming the semiconductor layer 430, if the semiconductor layer 430 is formed on the second electrode 420 under conditions in which the concentration of oxygen is insufficient, the concentration of oxygen vacancies in the semiconductor layer 430 may increase. In addition, when forming the semiconductor layer 430, if the semiconductor layer 430 is formed on the second electrode 420 under conditions in which the concentration of oxygen is sufficient, the concentration of oxygen vacancies in the semiconductor layer 430 may decrease. In this manner, when forming the semiconductor layer 430 on the second electrode 420, the concentration of oxygen vacancies in the semiconductor layer 430 may be adjusted by adjusting the oxygen concentration.

In addition, after forming the semiconductor layer 430 on the second electrode 420, a heat treatment process may be performed on the semiconductor layer 430 to control the concentration of oxygen vacancies in the semiconductor layer 430. For example, when heat treatment is performed on the semiconductor layer 430 in a low-oxygen atmosphere, oxygen may escape from the semiconductor layer 430 and the concentration of oxygen vacancies may increase. Conversely, if the heat treatment is performed on the semiconductor layer 430 in an oxygen-rich atmosphere, the concentration of oxygen vacancies in the semiconductor layer 430 may decrease.

According to some embodiments, instead of performing a heat treatment process on the exposed semiconductor layer 430 after forming the semiconductor layer 430 on the second electrode 420, the second insulating layer 450 may be formed on the semiconductor layer 430, a sacrificial layer rich in oxygen may be formed on the second insulating layer 450, and then a heat treatment process may be performed to reduce the concentration of oxygen vacancies in the semiconductor layer 430. The sacrificial layer may include, for example, an oxide semiconductor, and may be removed after the heat treatment process.

That is, after the semiconductor layer 430, the second insulating layer 450, and a sacrificial layer are sequentially stacked through a heat treatment process, oxygen included in the sacrificial layer may diffuse into the semiconductor layer 430 through the second insulating layer 450, thereby reducing the concentration of oxygen vacancies in the semiconductor layer 430. Thereafter, after the sacrificial layer is removed, the gate electrode 460 may be patterned on the second insulating layer 450, or the gate electrode 460 may be patterned on the sacrificial layer without removing the sacrificial layer.

In this manner, in the operation of forming the semiconductor layer 430, the concentration of oxygen may be adjusted when the semiconductor layer 430 is formed or a heat treatment process may be performed after the semiconductor layer 430 is formed to perform an operation of adjusting the concentration of oxygen vacancies in the semiconductor layer 430, thereby optimizing the electrical performance of the semiconductor layer 430.

Thereafter, the gate electrode 460 may be formed on the second insulating layer 450 and patterned through a photolithography process to manufacture the transistor 400 illustrated in FIG. 4.

According to some embodiments, if the thickness of the first electrode 410 is less than the sum of the thickness of the semiconductor layer 430 and the thickness of the second insulating layer 450, the lower surface of the gate electrode 460 may not be located below the upper surface of the first electrode 410. Accordingly, a region in which the semiconductor layer 430 and the gate electrode 460 do not overlap in a direction parallel to the upper surface of the substrate 100 may be created. As a result, the region in which the semiconductor layer 430 and the gate electrode 460 do not overlap in a direction parallel to the upper surface of the substrate 100 may act as resistance, causing a deterioration in the electrical performance of the transistor 400.

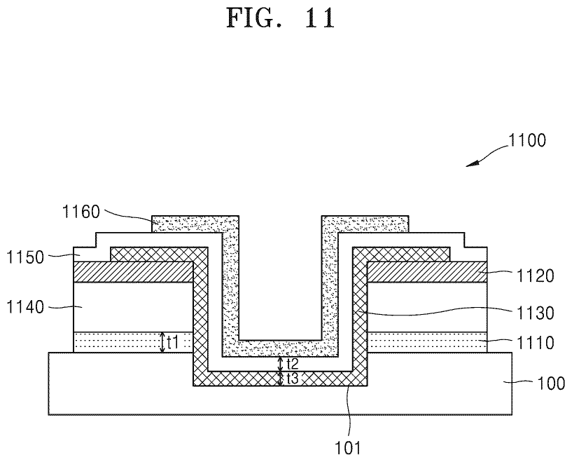

Accordingly, in case that the thickness of the first electrode 410 is less than the sum of the thickness of the semiconductor layer 430 and the thickness of the second insulating layer 450, an operation of over-etching a portion of the exposed substrate 100 or the buffer layer on the substrate 100 may be further included after the operation of forming the recess, Details thereof are described below with reference to FIG. 11.

According to some embodiments, after the transistor 400 is formed on the substrate 100, an operation of forming a light-emitting device that may be electrically connected to the transistor 400 may be further included.

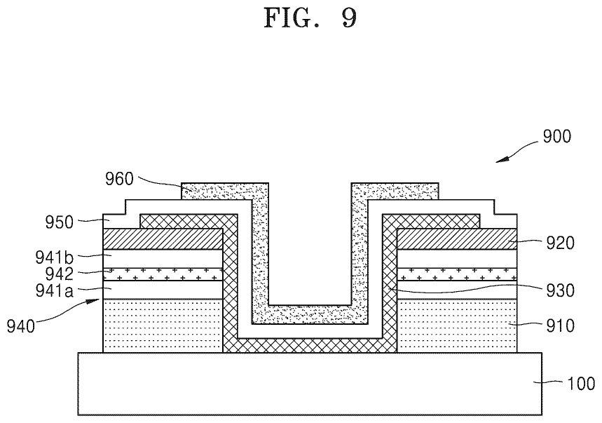

FIG. 9 is a cross-sectional view schematically illustrating aspects of a transistor 900 located in a sub-pixel included in the display device 10 of FIG. 1.

Referring to FIG. 9, the display device 10 according to some embodiments of the present disclosure may include the substrate 100, the transistor 900 on the substrate 100, and a light-emitting device electrically connected to the transistor 900. The transistor 900 may be a vertical thin-film transistor in which a channel is formed in a direction perpendicular to the substrate 100.

The transistor 900 may include a first electrode 910 positioned on the substrate 100, a second electrode 920 spaced apart vertically from the first electrode 910 with a first insulating layer 940 therebetween, and a semiconductor layer 930 in contact with the first electrode 910 and the second electrode 920.

A recess penetrating the second electrode 920, the first insulating layer 940, and the first electrode 910 from an upper surface of the second electrode 920 may be defined, at least a portion of the semiconductor layer 930 may be positioned within the recess, and within the recess, the semiconductor layer 930 may be in contact with a side surface of the first electrode 910, a side surface of the second electrode 920, and a bottom surface of the recess. In addition, the semiconductor layer 930 may extend outwardly of the recess on the upper surface of the second electrode 920 and may be in contact with the upper surface of the second electrode 920.

The first electrode 910, the second electrode 920, the semiconductor layer 930, the second insulating layer 950, and the gate electrode 960 are the same as the first electrode 410, the second electrode 420, the semiconductor layer 430, the second insulating layer 450, and the gate electrode 460 illustrated and described above with reference to FIG. 4, and therefore some repetitive description may be omitted.

The first insulating layer 940 may have a multilayer structure including a silicon nitride layer 942 and a silicon oxide layer 941. For example, the first insulating layer 940 may include a first silicon oxide layer 941a, a silicon nitride layer 942, and a second silicon oxide layer 941b sequentially stacked on the substrate 100.

The silicon nitride layer 942 has a relatively high dielectric constant, so the silicon nitride layer 942 may provide higher electrostatic capacitance at the same thickness. In addition, the silicon nitride layer 942 has excellent moisture and gas barrier properties and excellent mechanical strength and heat resistance, so the silicon nitride layer 942 may block moisture from penetrating into the semiconductor layer 930, thereby relatively improving the durability of the transistor 900.

The first and second silicon oxide layers 941a, 941b have a relatively low dielectric constant, so the first and second silicon oxide layers 941a, 941b may provide high insulating properties to the transistor 900 and may reduce leakage current of the gate electrode 960.

Therefore, according to some embodiments of the present disclosure, when the first insulating layer 940 includes the first silicon oxide layer 941a, the silicon nitride layer 942, and the second silicon oxide layer 941b sequentially stacked on the substrate 100, the advantages of the silicon nitride layer 942 and the first and second silicon oxide layers 941a, 941b may be combined, so that the electrical characteristics and physical characteristics of the transistor 900 may be relatively improved compared to when the silicon nitride layer 942 and the first and second silicon oxide layers 941a, 941b are used alone.

According to some embodiments, as described above, when the semiconductor layer 930 includes an oxide semiconductor, the concentration of oxygen vacancies in the semiconductor layer 930 may have a significant effect on the electrical characteristics of the transistor 900.

When a silicon nitride layer that may be included in the first insulating layer 940 and the second insulating layer 950 is formed, silane (SiH₄) or ammonia (NH³) including hydrogen may be used as a precursor. Here, the included hydrogen may diffuse into the semiconductor layer 930 in contact with the first insulating layer 940 and the second insulating layer 950.

When hydrogen diffuses into the semiconductor layer 930 including an oxide semiconductor, hydrogen may neutralize oxygen vacancies in the semiconductor layer 930. Accordingly, the conductivity of the transistor 900 may be reduced and a threshold voltage of the transistor 900 may be varied, thereby reducing the switching performance of the transistor 900.

However, according to some embodiments of the present disclosure, when the first insulating layer 940 has a multilayer structure including a silicon nitride layer and a silicon oxide layer, even if the semiconductor layer 930 is in contact with the first insulating layer 940, the diffusion of hydrogen from the silicon nitride layer 942 to the semiconductor layer 930 may be minimized by adjusting the thicknesses of the first silicon oxide layer 941a, the second silicon oxide layer 941b, and the silicon nitride layer 942, and the advantages of the multilayer structure of the silicon nitride layer 942 and the first and second silicon oxide layers 941a, 941b described above may be enjoyed.

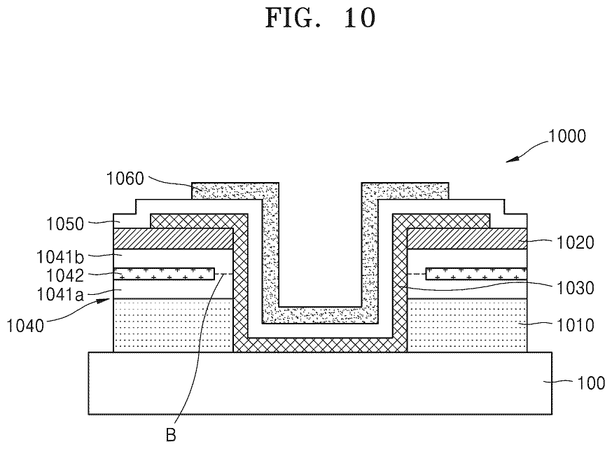

FIG. 10 is a cross-sectional diagram schematically aspects of a transistor 1000 located in a sub-pixel included in the display device 10 of FIG. 1.

Referring to FIG. 10, the display device 10 according to some embodiments of the present disclosure may include the substrate 100, the transistor 1000 on the substrate 100, and a light-emitting device electrically connected to the transistor 1000. The transistor 1000 may be a vertical thin-film transistor in which a channel is formed in a direction perpendicular to the substrate 100.

The transistor 1000 may include a first electrode 1010 positioned on the substrate 100, a second electrode 1020 spaced apart in a vertical direction from the first electrode 1010 with a first insulating layer 1040 therebetween, and a semiconductor layer 1030 in contact with the first electrode 1010 and the second electrode 1020.

A recess penetrating the second electrode 1020, the first insulating layer 1040, and the first electrode 1010 from an upper surface of the second electrode 1020 may be defined, at least a portion of the semiconductor layer 1030 may be positioned within the recess, and within the recess, the semiconductor layer 1030 may be in contact with a side surface of the first electrode 1010, a side surface of the second electrode 1020, and a bottom surface of the recess. In addition, the semiconductor layer 1030 may extend outwardly of the recess from the upper surface of the second electrode 1020 and may be in contact with the upper surface of the second electrode 1020.

The first electrode 1010, the second electrode 1020, the semiconductor layer 1030, the second insulating layer 1050, and the gate electrode 1060 are the same as the first electrode 410, the second electrode 420, the semiconductor layer 430, the second insulating layer 450, and the gate electrode 460 illustrated and described above with reference to FIG. 4, and therefore some repetitive description may be omitted.

The first insulating layer 1040 may have a multilayer structure including a silicon nitride layer 1042 and silicon oxide layers 1041a and 1041b. For example, the silicon nitride layer 1042 may be spaced apart from the semiconductor layer 1030. That is, the semiconductor layer 1030 may be in contact with the silicon oxide layers 1041a and 1041b and may not be in contact with the silicon nitride layer 1042.

As described above, in case that the semiconductor layer 1030 contacts the silicon nitride layer 1042 included in the first insulating layer 1040, hydrogen occurring during the formation of the silicon nitride layer 1042 may diffuse into the semiconductor layer 1030, thereby reducing the concentration of oxygen vacancies in the semiconductor layer.

However, according to some embodiments of the present disclosure, when the silicon nitride layer 1042 is spaced apart from the semiconductor layer 1030, the silicon nitride layer 1042 may not be in direct contact with the semiconductor layer 1030. As a result, diffusion of hydrogen from the silicon nitride layer 1042 to the semiconductor layer 1030 may be prevented or reduced.

In addition, by combining the afore-mentioned advantages of the silicon nitride layer 1042 and the silicon oxide layers 1041a and 1041b, the electrical characteristics and physical characteristics of the transistor 1000 may be relatively improved compared to when the silicon nitride layer 1042 and the silicon oxide layers 1041a and 1041b are used alone.

The method of forming the silicon nitride layer 1042 to be spaced apart from the semiconductor layer 1030 is as follows: when forming the first insulating layer 1040 on the first electrode 1010, the first silicon oxide layer 1041a is deposited on the first electrode 1010, and then the silicon nitride layer 1042 is deposited on the first silicon oxide layer 1041a. Thereafter, the silicon nitride layer 1042 is patterned, and the second silicon oxide layer 1041b is then deposited.

The silicon nitride layer 1042 may be formed to be spaced apart from the semiconductor layer 1030 by the above method. Here, a boundary surface B may be formed between the first silicon oxide layer 1041a and the second silicon oxide layer 1041b, but the boundary surface B may be faint and not easily visible.

According to some embodiments, in FIGS. 9 and 10, it is described that the first insulating layer 940 or 1040 may have a multilayer structure including the silicon nitride layer 942 or 1042 and the silicon oxide layer 941 or 1041, and it is also obvious that the second insulating layer 950 or 1050 may have a multilayer structure including the silicon nitride layer 942 or 1042 and the silicon oxide layer 941 or 1041, similar to the first insulating layer 940 or 1040 described above with reference to FIGS. 9 and 10.

FIG. 11 is a cross-sectional diagram schematically illustrating aspects of a transistor 1100 located in a sub-pixel included in the display device 10 of FIG. 1.

Referring to FIG. 11, the display device 10 according to some embodiments of the present disclosure may include the substrate 100, the transistor 1100 on the substrate 100, and a light-emitting device electrically connected to the transistor 1100. The transistor 1100 may be a vertical thin-film transistor in which a channel is formed in a direction perpendicular to the substrate 100.

The transistor 1100 may include a first electrode 1110 positioned on the substrate 100, a second electrode 1120 spaced apart in a vertical direction from the first electrode 1110 with a first insulating layer 1140 therebetween, and a semiconductor layer 1130 in contact with the first electrode 1110 and the second electrode 1120.

A recess penetrating the second electrode 1120, the first insulating layer 1140, and the first electrode 1110 from an upper surface of the second electrode 1120 may be defined, at least a portion of the semiconductor layer 1130 may be positioned within the recess, and within the recess, the semiconductor layer 1130 may be in contact with a side surface of the first electrode 1110, a side surface of the second electrode 1120, and a bottom surface of the recess. In addition, the semiconductor layer 1130 may extend outwardly of the recess on the upper surface of the second electrode 1120 and may be in contact with the upper surface of the second electrode 1120.

The first electrode 1110, the second electrode 1120, the semiconductor layer 1130, the first insulating layer 1140, the second insulating layer 1150, and the gate electrode 1160 are the same as the first electrode 410, the second electrode 420, the semiconductor layer 430, the first insulating layer 440, the second insulating layer 450, and the gate electrode 460 illustrated and described above with reference to FIG. 4, and therefore some repetitive description may be omitted.

When a thickness t1 of the first electrode 1110 is less than the sum of a thickness t3 of the semiconductor layer 1130 and a thickness t2 of the second insulating layer 1150, a lower surface of the gate electrode 1160 may not be located below the upper surface of the first electrode 1110. Accordingly, a region in which the semiconductor layer 1130 and the gate electrode 1160 do not overlap in a direction parallel to the upper surface of the substrate 100 may be created, thereby deteriorating the electrical characteristics of the transistor 1100.

Therefore, in case that the thickness t1 of the first electrode 1110 is less than the sum of the thickness t3 of the semiconductor layer 1130 and the thickness t2 of the second insulating layer 1150, an operation of over-etching a portion of the exposed substrate 100 or the buffer layer on the substrate 100 may be further included, after the operation of forming the recess.

In this manner, the exposed substrate 100 or the buffer layer on the substrate 100 is additionally etched, the substrate 100 or the buffer layer on the substrate 100 may include a recess 101 led into the interior, and the semiconductor layer 1130 may be positioned within the recess 101. That is, in the substrate 100 or the buffer layer on the substrate 100, a first thickness overlapping the recess may be less than a second thickness outside the recess. In addition, at a position overlapping the recess, a lower surface of the semiconductor layer 1130 may be positioned at a lower height than the upper surface of the substrate 100 outside the recess.

As a result, even when the thickness t1 of the first electrode 1110 is less than the sum of the thickness t3 of the semiconductor layer 1130 and the thickness t2 of the second insulating layer 1150, a lower surface of the gate electrode 1160 may be positioned at a lower height than the upper surface of the first electrode 1110 because the semiconductor layer 1130, the second insulating layer 1150, and the gate electrode 1160 are sequentially formed within the recess 101 of the substrate 100 or the buffer layer on the substrate 100.

Accordingly, the entire region of the channel region of the semiconductor layer 1130 may overlap the gate electrode 1160, so that the channel region may fully receive the electric field of the gate electrode 1160 to form a channel, and the semiconductor layer 1130 and the first electrode 1110 may contact the inner surface of the recess, so that parasitic capacitance between the first electrode 1110 and the gate electrode 1160 may be prevented or reduced, thereby relatively improving the electrical characteristics and power efficiency of the display device 10 and an electronic device including the same.

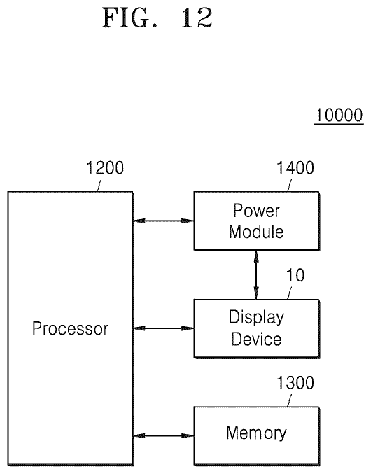

FIG. 12 is a block diagram of an electronic device 10000 according to some embodiments.

Referring to FIG. 12, the electronic device 10000 according to some embodiments may include the display device 10, a processor 1200, a memory 1300, and a power module 1400.

The display device 10 may receive data from the processor 1200 and provide visual information. The display device 10 may be the display device 10 according to the embodiments of the present disclosure described above.

The processor 1200 may include at least one of a central processing unit (CPU), an application processor (AP), a graphic processing unit (GPU), a communication processor (CP), an image signal processor (ISP), and a controller. For example, the processor 1200 may operate by executing at least one program.

Data information necessary for the operation of the processor 1200 or display device 10 may be stored in the memory 1300. For example, the memory 1300 may store the at least one of the program. When the processor 1200 executes an application stored in the memory 1300, an image data signal and/or an input control signal may be transmitted to the display device 10, and the display device 10 may process the received signal and output image information through a display screen.

The power module 1400 may include a power supply module, such as a power adapter or a battery device, and a power conversion module that converts power supplied by the power supply module to generate power required for the operation of the electronic device 10000. For example, the power module 1400 may supply power to the display device 10.

At least one of the components of the electronic device 10000 described above may be included in the display device 10 according to the embodiments described above. In addition, some of the individual modules functionally included in one module may be included in the display device 10 and others may be provided separately from the display device 10.

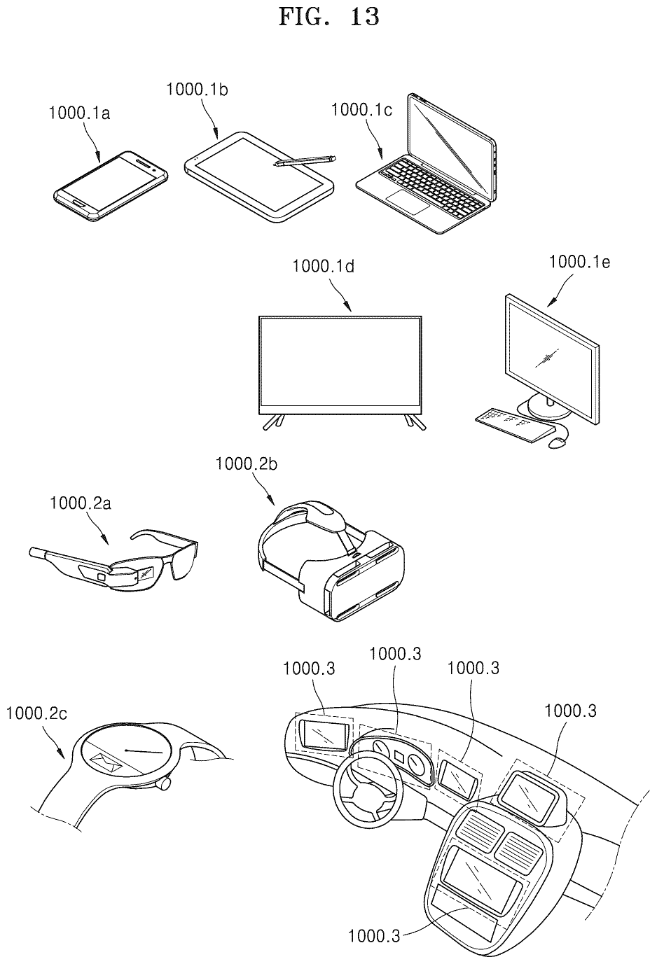

FIG. 13 is a schematic diagram of an electronic device according to various embodiments.

Referring to FIG. 13, various electronic devices to which the display device according to some embodiments of the present disclosure is applied may include not only electronic devices for image display, such as a smartphone 1000.1a, a tablet PC 1000.1b, a laptop 1000.1c, a TV 1000.1d, a desk monitor 1000.1e, but also wearable electronic devices including display devices, such as smart glasses 1000.2a, a head mounted display 1000.2b, a smart watch 1000.2c, and the like, and vehicle electronic devices 1000.3 including display devices, such as a center information display (CID) and a room mirror display placed on a dashboard, center fascia, or dashboard of an automobile.

Each of the embodiments described above may be implemented independently, but the structure of each embodiment may be applied in combination to other embodiments.

According to some embodiments of the present disclosure, a display device according to some embodiments of the present disclosure includes a vertical transistor in which a lowermost surface of a gate electrode is positioned below an uppermost surface of a first electrode, thereby preventing or reducing parasitic capacitance between the gate electrode and the first electrode, and preventing or reducing a part of a semiconductor layer from not receiving an electric field of the gate electrode and acting as a resistor, thereby relatively improving power efficiency and electrical characteristics of the display device and an electronic device including the same.

However, the effects obtainable through the present disclosure are not limited to the effects described above, and other technical effects not mentioned will be clearly understood by those skilled in the art from the description of the disclosure described below.

As such, the present disclosure has been described with reference to the embodiments shown in the drawings, but these are merely illustrative, and those skilled in the art will understand that various modifications and equivalent other embodiments may be made therefrom. Therefore, the true scope of technical protection of the present disclosure should be determined by the technical spirit of the appended patent claims.

Specific implementations described in the embodiments are examples and do not limit the scope of the embodiments in any way. Moreover, no component is essential to the practice of the present disclosure, unless the component is for example described as “essential” or “critical”.

In the specification of the embodiment (particularly in the claims), the use of the terms “a” and “an” and “the” and similar referents may be construed to cover both the singular and the plural.

Furthermore, recitation of ranges of values herein are merely intended to serve as a shorthand method of referring individually to each separate value falling within the range, unless otherwise indicated herein, and each separate value is incorporated into the specification as if it were individually recited herein.

Lastly, the steps of all methods described herein may be performed in any suitable order unless otherwise indicated herein or otherwise clearly contradicted by context. The embodiments are not necessarily limited by the order of description of the steps above.

The use of any and all examples, or example language (e.g., “such as”) provided herein is intended merely to better describe the present disclosure and the scope of the embodiments is not limited by the examples or illustrative terms, unless limited by the claims.

In addition, those skilled in the art may recognize that various modifications, combinations and changes may be made depending on design conditions and factors within the scope of the appended claims or their equivalents.

What is claimed is:

1. A display device comprising:
a substrate;
a transistor on the substrate; and
a light-emitting device electrically connected to the transistor,
wherein the transistor includes:
a first electrode on the substrate;
a second electrode spaced apart from the first electrode in a vertical direction with a first insulating layer therebetween;
a semiconductor layer contacting the first electrode and the second electrode; and
a gate electrode overlapping the semiconductor layer with a second insulating layer therebetween,
wherein a recess penetrates the second electrode, the first insulating layer, and the first electrode from an upper surface of the second electrode,
at least a portion of the semiconductor layer and at least a portion of the gate electrode are located within the recess, and
within the recess, the semiconductor layer contacts a side surface of the first electrode and a side surface of the second electrode, and a lower surface of the gate electrode is at a lower height than an upper surface of the first electrode.

2. The display device of claim 1, wherein a shape of the gate electrode corresponds to a shape of the semiconductor layer.

3. The display device of claim 1, wherein the semiconductor layer extends outwardly of the recess on the upper surface of the second electrode.

4. The display device of claim 1, wherein the first insulating layer has a multilayer structure including a silicon nitride layer and a silicon oxide layer.

5. The display device of claim 4, wherein the silicon nitride layer is spaced apart from the semiconductor layer.

6. The display device of claim 4, wherein the first insulating layer includes a first silicon oxide layer, a silicon nitride layer, and a second silicon oxide layer sequentially stacked on the substrate.

7. The display device of claim 1, wherein
the substrate has a first thickness overlapping the recess and a second thickness outside the recess, the first thickness being less than the second thickness, and
at a position overlapping the recess, a lower surface of the semiconductor layer is positioned at a lower height than an upper surface of the substrate outside the recess.

8. The display device of claim 7, wherein a thickness of the first electrode is less than a sum of a thickness of the semiconductor layer and a thickness of the second insulating layer.

9. The display device of claim 1, wherein the semiconductor layer includes an oxide semiconductor.

10. The display device of claim 1, wherein the transistor includes a switching transistor.

11. A method of manufacturing a display device, wherein the method comprising:
sequentially forming a first electrode, a first insulating layer, and a second electrode on a substrate;
patterning the first electrode, the first insulating layer and the second electrode to form a recess penetrating the second electrode, the first insulating layer and the first electrode from an upper surface of the second electrode;
forming a semiconductor layer and a second insulating layer within at least the recess; and
forming a gate electrode on the second insulating layer,
wherein a lower surface of the gate electrode is positioned at a lower height than an upper surface of the first electrode.

12. The method of claim 11, further comprising:
etching a portion of the substrate, after the forming of the recess.

13. The method of claim 12, wherein
the substrate has a first thickness overlapping the recess and a second thickness outside the recess, the first thickness being less than a second thickness, and
at a position overlapping the recess, a lower surface of the semiconductor layer is positioned at a lower height than an upper surface of the substrate outside the recess.

14. The method of claim 11, wherein the semiconductor layer includes an oxide semiconductor.

15. The method of claim 11, wherein
forming the semiconductor layer and the second insulating layer includes adjusting a concentration of oxygen vacancies in the semiconductor layer by adjusting a concentration of oxygen when forming the semiconductor layer or performing a heat treatment process after forming the semiconductor layer.

16. The method of claim 11, wherein a shape of the gate electrode corresponds to a shape of the semiconductor layer.

17. The method of claim 11, wherein, within the recess, the semiconductor layer contacts a side surface of the first electrode and a side surface of the second electrode.

18. The method of claim 11, wherein the first insulating layer has a multilayer structure including a silicon nitride layer and a silicon oxide layer.

19. The method of claim 11, wherein the first electrode, and the second electrode form a portion of a transistor, the method further comprising:
forming a light-emitting device electrically connected to the transistor.

20. . An electronic device comprising:
program;
a processor configured to operate by executing the at least one of the program;
a display device configured to receive data from the processor and provide visual information; and
a power module configured to supply power to the display device;
wherein the display device includes:
a substrate;
a transistor on the substrate; and
a light-emitting device electrically connected to the transistor,
wherein the transistor includes:
a first electrode on the substrate;
a second electrode spaced apart from the first electrode with a first insulating layer therebetween;
a semiconductor layer contacting the first electrode and the second electrode; and
a gate electrode overlapping the semiconductor layer with a second insulating layer therebetween,
wherein a recess penetrates the second electrode, the first insulating layer, and the first electrode from an upper surface of the second electrode,
at least a portion of the semiconductor layer and at least a portion of the gate electrode are located within the recess, and
within the recess, the semiconductor layer contacts with a side surface of the first electrode, a side surface of the second electrode, and a bottom surface of the recess, and a lower surface of the gate electrode is at a lower height than an upper surface of the first electrode.
